(19) United States
(12) Patent Application Publication
(10) Pub. No.: US 2015/0360316 A1
(43) Pub. Date: Dec. 17, 2015

(54) COATED WIRE FOR BONDING APPLICATIONS

(71) Applicant: HERAEUS DEUTSCHLAND GMBH & CO. KG, Hanau (DE)

(72) Inventors: Eugen MILKE, Nidderau (DE); Jürgen SCHARF, Mömbris (DE)

(73) Assignee: HERAEUS DEUTSCHLAND GMBH & CO. KG, Hanau (DE)

(21) Appl. No.: 14/762,556

(22) PCT Filed: Dec. 18, 2013
(86) PCT No.: PCT/EP2013/077146

§ 371 Date: Jul. 22, 2015

(30) Foreign Application Priority Data
Jan. 23, 2013 (EP) 13000342.9
Apr. 29, 2013 (EP) 13002254.4

(51) Int. Cl. B23K 20/00; B23K 35/30; B23K 35/40; H05K 3/34; C25D 5/34; H01L 23/00; H05K 1/09; B23K 35/02; C25D 7/06

(52) U.S. Cl. CPC B23K 20/007; B23K 35/0272; B23K 35/3006; B23K 35/302; B23K 35/404; C25D 7/0607; C25D 5/34; H01L 24/45; H01L 24/43; H01L 24/48; H01L 24/78; H01L 24/85; H05K 1/09; H05K 3/34; H01L 2224/45139; H01L 2224/45147; H01L 2224/45664; H01L 2224/45669; H01L 2224/45644; H01L 2224/45673; H01L 2224/45676; H01L 2224/45678; H01L 2224/45663; H01L 2924/01076; H01L 2224/4556; H01L 2224/45565; H01L 2224/43125; H01L 2224/435; H01L 2224/432; H01L 2224/4845; H01L 2224/48455; H01L 2224/85801; H01L 2224/48247; H01L 2224/43823; H01L 2224/43825; H01L 2224/43826; H05K 2201/10287; H05K 2203/049

(57) ABSTRACT

The invention is related to a bonding wire which contains a core having a surface and a coating layer which is at least partially superimposed over the surface of the core. The core contains a core main component selected from copper and silver. The coating layer contains a coating component selected from palladium, platinum, gold, rhodium, ruthenium, osmium and iridium in an amount of at least 10% and further contains the core main component in an amount of at least 10%.

### CROSS-REFERENCE TO RELATED APPLICATIONS

This application is a Section 371 of International Application No. PCT/EP2013/077146, filed Dec. 18, 2013, which was published in the English language on Jul. 31, 2014 under International Publication No. WO 2014/114412 A1, and the disclosure of which is incorporated herein by reference.

### BACKGROUND OF THE INVENTION

Bonding wires are used in the manufacture of semiconductor devices for electrically interconnecting an integrated circuit and a printed circuit board during semiconductor device fabrication. Further, bonding wires are used in power electronic applications to electrically connect transistors, diodes and the like with pads or pins of the housing. While bonding wires were originally made from gold, nowadays less expensive materials, such as copper, are used. While copper wire provides very good electric and thermal conductivity, wedge-bonding of copper wire has its challenges. Moreover, copper wires are susceptible to oxidation.

With respect to wire geometry, most common are bonding wires of circular cross-section and bonding ribbons, which have a more or less rectangular cross-section. Both types of wire geometries have their advantages, making them useful for specific applications. Thus, both types of geometry have their share in the market. For example, bonding ribbons have a larger contact area for a given cross-sectional area. However, bending of the ribbons is limited and orientation of the ribbon must be observed when bonding in order to arrive at acceptable electrical contact between the ribbon and the element to which it is bonded. Turning to bonding wires, these are more flexible to bending. However, bonding involves either soldering or larger deformation of the wire in the bonding process, which may cause harm or even destroy the bonding pad and underlying electric structures of the element which is bonded thereto.

The term bonding wire may be understood to comprise all shapes of cross-sections and all usual wire diameters, though bonding wires with circular cross-section and thin diameters are preferred.

Some recent developments were directed to bonding wires having a copper core and a protective coating layer. As a core material, copper is chosen because of high electric conductivity. With regard to the coating layer, palladium is one of the possible choices. These coated bonding wires combine the advantages of the copper wire with less sensitivity to oxidation. Nevertheless, there is an ongoing need for further improving bonding wire technology with regard to the bonding wire itself and the bonding processes.

### BRIEF SUMMARY OF THE INVENTION

It is an object of the invention to provide improved bonding wires.

It is another object of the invention to provide a bonding wire which has good processing properties and which has no specific needs when interconnecting, thus saving costs.

It is also an object of the invention to provide a bonding wire which has excellent electrical and thermal conductivity.

It is a further object of the invention to provide a bonding wire which exhibits improved reliability.

It is a further object of the invention to provide a bonding wire which exhibits excellent bondability, in particular with respect to the forming of a free air ball (FAB) in the course of a ball bonding procedure.

It is another object of the invention to provide a bonding wire which shows good bondability with respect to a wedge bonding and/or second bonding.

It is another object of the invention to provide a bonding wire which has improved resistance to corrosion and/or oxidation.

It is another object to provide a system for bonding an electronic device, to be used with standard chip and bonding technology, which system shows reduced failure rate at least with respect to a first bonding.

It is another object to provide a method for manufacturing an inventive bonding wire which requires essentially no increase in manufacturing costs compared with known methods.

Thus, the invention is related to a bonding wire comprising a core having a surface and a coating layer which is at least partially superimposed over the surface of the core, wherein the core comprises a core main component selected from the group consisting of copper and silver. The coating layer comprises a coating component selected from palladium, platinum, gold, rhodium, ruthenium, osmium and iridium in an amount of at least 10% and also comprises the main component of the core in an amount of at least 10%.

The invention further relates to a system for bonding an electronic device, comprising a first bonding pad, a second bonding pad and a wire according to the invention, wherein the inventive wire is connected to at least one of the bonding pads by wedge-bonding.

The invention further relates to a method for manufacturing a wire according to the invention.

Surprisingly, the inventive wires have been found to solve at least one of the objects mentioned above. Further, several alternative processes for manufacturing these wires have been found, which overcome at least one of the challenges of manufacturing wires. Systems comprising the wires of the invention were found to be more reliable at the interface between the wire according to the invention and other electrical elements, e.g., the printed circuit board, the pad/pin etc.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a diagram of a wire according to an embodiment of the invention;

FIG. 2 is a cross-sectional view of the wire shown in FIG. 1;

FIG. 3 is a flowchart of a process for manufacturing a wire according to a further embodiment of the invention;

FIG. 4 is a diagram of an electronic device according to another embodiment of the invention;

FIG. 5 is a diagram of wire coating equipment according to a further embodiment of the invention; and

FIG. 6 is an Auger depth profile of a wire according to another embodiment of the invention.

### DETAILED DESCRIPTION OF THE INVENTION

A first aspect of the invention is a bonding wire comprising a core having a surface and a coating layer which is at least partially superimposed over the surface of the core. The core comprises a core main component selected from the group consisting of copper and silver. The coating layer comprises a coating component selected from palladium, platinum, gold, rhodium, ruthenium, osmium and iridium in an amount of at least 10% and also comprises the core main component in an amount of at least 10%.

More preferred embodiments have one of the following combinations of core main component and coating component:

| Core main component | Coating component |
|---|---|
| Cu | Pd |
| Cu | Pt |
| Ag | Au |
| Ag | Pd |
| Ag | Pt |

In a more preferred embodiment, the core main component and the coating component are each present in an amount of at least 20%, and most preferably in amounts of at least 25%.

Such wires according to the invention have an optimized coating layer with respect to cost of production and effectiveness. It has surprisingly been found that there are no drawback of corrosion resistance or other properties if the coating layer does not consist of the pure coating component, but rather contains significant shares of the core main component.

If no other specific definition is provided, all contents or shares of components are presently given as shares in mole-%. In particular, shares given in percent may be understood to be mole-%, and shares given in ppm (parts per million) may be understood to be mole-ppm.

In the case of the present invention, Auger Depth Profiling is chosen as the method for defining the composition of the coating layer. In this method, the elemental composition is measured by means of Auger analysis on a respective surface of the wire. The composition of the coating layer at different depths with respect to the surface of the coating layer is measured by sputter depth profiling. When the coating layer is sputtered by an ion beam at a defined rate, the composition is followed by accompanying Auger analysis.

The amounts of the core main component and/or the coating component in the coating layer may be understood to be averaged over the entire volume of the coating layer if no other specification is given.

An interface region between the coating layer and the wire core is usually present, like in all real systems of layered structures. Such an interface region may be more or less narrow, depending on the wire manufacturing method and further parameters. For the purpose of clarity hereinafter, a border of the coating layer and/or the wire core is usually defined as a given percentage drop of a component signal in a depth profiling measurement.

The term “superimposed” in the context of this invention is used to describe the relative position of a first item, e.g., a copper core, with respect to a second item, e.g., a coating layer. Possibly, further items, such as an intermediate layer, may be arranged between the first and the second item. Preferably, the second item is at least partially superimposed over the first item, e.g., for at least 30%, 50%, 70%, or for at least 90% with respect to the total surface of the first item.

Most preferably, the second item is completely superimposed over the first item. Generally preferably, the coating layer is an outermost layer of the bonding wire. However, in other embodiments, the coating layer may be superimposed by a further layer.

The wire according to the invention is a bonding wire, in particular for bonding in microelectronics. The wire is preferably a one-piece object.

A component is a “main component” if the share of this component exceeds all other components of a referenced material. Preferably, a main component comprises at least 50% of the total weight of the material.

The core of the inventive wire preferably comprises copper or silver in an amount of at least 90%, more preferably at least 95%. In other embodiments, copper and silver may be simultaneously present, wherein one of the two elements represents the core main component. In a most preferred embodiment of the invention, the wire core consists of pure copper, wherein a sum of components other than copper is less than 0.1%.

In the case of an alternative advantageous embodiment of the invention, the core main component is copper and may comprise small amounts of palladium, in particular less than 5%, as a component. More preferably, the amount of palladium in the core is between 0.5% and 2%, most preferably between 1.1% and 1.8%. In such case, the sum of components other than copper and palladium is preferably less than 0.1%.

Generally preferred are embodiments in which the coating layer has a thickness of less than 0.5 μm. If the coating layer is sufficiently thin, possible effects of the coating layer in the bonding process are reduced. The term “thickness” in the context of this invention is used to define the size of a layer in a perpendicular direction to the longitudinal axis of the wire core, which layer is at least partially superimposed over the surface of the wire core.

The present invention is particularly related to thin bonding wires. The observed effects are particularly beneficial to thin wires, for example because of the sensitivity to oxidation of such wires. In the present case, the term “thin wire” is defined as a wire having a diameter in the range of 8 μm to 80 μm. Most preferably, a thin bonding wire according to the invention has a thickness in the range of 12 μm to 50 μm.

Such thin wires usually, but not necessarily, have a cross-sectional view essentially in the shape of a circle. The term “a cross-sectional view” in the present context refers to a view of a cut through the wire, wherein the plane of the cut is perpendicular to the longitudinal extension of the wire. The cross-sectional view may be found at any position on the longitudinal extension of the wire. A “longest path” through the wire in a cross-section is the longest chord which may be laid through the cross-section of the wire within the plane of the cross-sectional view. A “shortest path” through the wire in a cross-section is the longest chord perpendicular to the longest path within the plane of the cross-sectional view defined above. If the wire has a perfectly circular cross-section, the longest path and the shortest path become indistinguishable and have the same value. The term “diameter” is the arithmetic mean of all geometric diameters of any plane and in any direction, wherein all planes are perpendicular to the longitudinal extension of the wire.

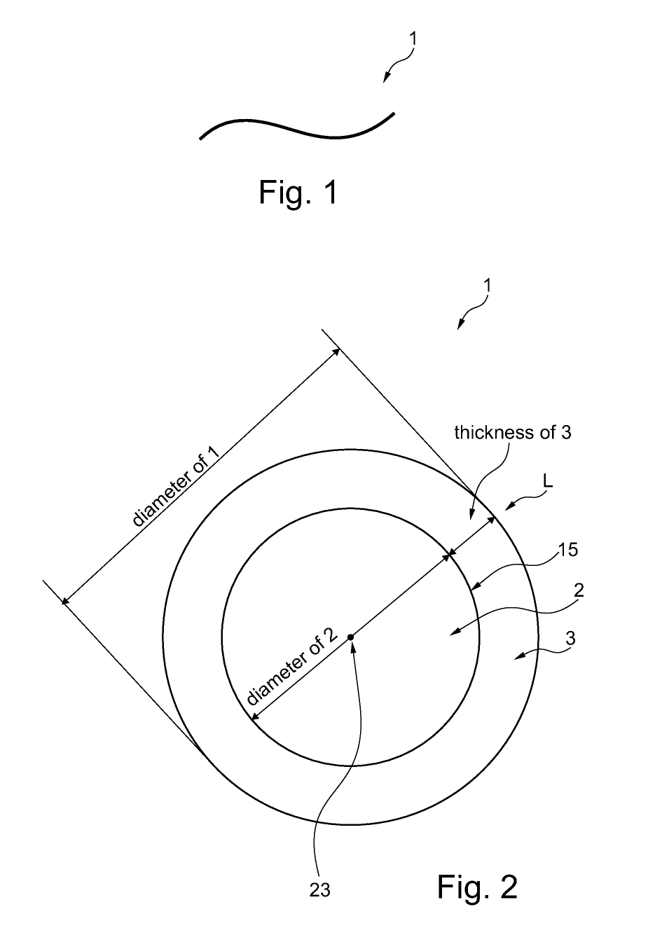

In FIG. 1, a wire 1 is depicted. FIG. 2 shows a cross sectional view of wire 1. In the cross sectional view, a copper core 2 is in the middle and is encompassed by a coating layer 3. On the outer limit of copper wire 2, a surface 15 of the copper core is located. On a line L through the center 23 of wire 1, the diameter of copper core 2 is shown as the end-to-end distance between the intersections of line L with the surface 15. The diameter of wire 1 is the end-to-end distance between the intersections of line L through the center 23 and the outer limit of wire 1. The thickness of coating layer 3 is also shown.

In a preferred embodiment of the invention, an outer range of the coating layer extends from a depth of 0.1% of a wire diameter to a depth of 0.25% of the diameter of the wire, and the amount of the core main component and the amount of the coating component are present in the outer range. Experiments have shown that the formation of a free air ball is particularly good if an amount of the core main component is present in outer portions of the coating layer. Even more preferably, the outer range starts at a depth of 0.05% of the diameter.

Generally preferably, the thickness of the coating layer roughly scales with the wire diameter, at least within certain ranges. At least in the case of thin wires, a total thickness of the coating layer is preferably between about 0.3% and 0.6% of the wire diameter.

In particular embodiments, a large amount of the core main component may also extend to the outer surface of the coating layer, but in other embodiments the very outermost part of the coating layer predominantly contains further substances like carbon or oxygen.

In yet further embodiments, the outermost surface of the coating layer may be covered with a few monolayers of a noble metal like gold or platinum, or even with a mixture of noble metals. In a particularly preferred embodiment of the invention, the coating layer is covered with a top layer having a thickness between 1 nm and 100 nm. Preferably, the thickness of the top layer is between 1 nm and 50 nm, and most preferably between 1 nm and 25 nm. Such a top layer preferably consists of a noble metal or an alloy of one or more noble metals. Preferred noble metals are selected from gold, silver and their alloys.

In a preferred embodiment, the amount of the core main component is between 30% and 70%, more preferably between 40% and 60%, in the outer range. Further advantageously, the rest of the outer range consists of the coating component, apart from additions or contaminations in an amount of less than 5%.

In a yet further development, the amount of the coating component decreases within the outer range toward the inside of the wire. It is particularly preferred if the difference between the amount of the coating component at a radially inner border of the outer range and the amount of the coating component at a radially outer border of the outer range is not more than 30%. Such a decreasing slope of the coating component toward the wire inside seems to add to the quality of the free air ball.

In a possible embodiment of the invention, the main component of the wire changes at least two times, starting from the outside of the wire to a depth of 0.25% of the diameter of the wire.

In this respect, a “main component” of the wire may be understood to be the highest elemental component in a small area at a certain depth. The wire is assumed to be composed rotationally symmetrically about its center axis. In such an ideal wire, the small area at a certain depth may be understood to be a cylinder wall of infinitesimal thickness which concentrically surrounds the wire axis. The depth of this area is then half of the difference between the wire diameter and the cylinder diameter.

The change of the main component may happen between three or even more components, e.g., starting with carbon, then changing a first time to palladium, and then changing a second time to copper as the main component. There may be more than two changes as well, for example if a multilayer structure of the coating layer is chosen to manufacture the coating layer.

In preferred embodiments, the number of changes of the main component is at least two, if carbon is not counted to be a component of the wire. If carbon is counted as a component of the wire, the preferred minimum number of changes of the main component is at least three.

Generally advantageously, an outer surface range of the coating layer contains carbon as a main component. The carbon may be present as elemental carbon or as an organic substance. Generally, such outer an surface range has a thickness of just a few monolayers, in particular less than 5 nm.

In a particularly preferred embodiment, an average grain size of the coating layer, measured at the wire surface in a longitudinal direction of the wire, is between 50 nm and 1000 nm. More preferably, the grain size is between 200 nm and 800 nm, most preferably between 300 nm and 700 nm.

For the determination of grain sizes, wire samples have been prepared, measured and evaluated by use of electron microscopy, in particular by EBSD (Electron Backscatter Diffraction). For the definition of a grain boundary, a tolerance angle of 5° has been set. The EBSD measurement is performed on a native surface of the bonding wire without any further preparation steps such as etching, etc. The size of a respective grain measured in a given direction is the maximum diameter of the grain in that specified direction.

In an advantageous embodiment, a ratio a/b of an average grain size a of the coating layer, measured at the wire surface in a longitudinal direction of the wire, to an average grain size b of the coating layer, measured at the wire surface in a circumferential direction of the wire, is between 0.1 and 10. More preferably, the ratio is between 0.3 and 3, and most preferably the ratio is between 0.5 and 2. The closer the ratio is to 1, the more isotropic are the crystal grains of the coating layer. An isotropic crystal structure of the coating layer helps to increase the quality of the FAB.

A further aspect of the invention is a method for manufacturing a wire according to the invention, comprising the steps of
a. providing a core precursor comprising copper or silver as a main component;
b. depositing a first auxiliary layer on the core precursor, wherein the first layer comprises the core main component or a coating component as a main component;
c. depositing a second auxiliary layer on the first auxiliary layer, wherein the second layer comprises the other of the core main component and the coating component as a main component; and
d. introducing energy into at least the first and second layers, thereby at least partially mixing the materials of the first and second layers.

An auxiliary layer in the sense of the invention is any layer which at least partially undergoes compositional or structural changes before the final wire is provided. The affected auxiliary layers are finally part of the coating layer in the sense of the invention. In step d of the invention, at least a partial mixing of the layers with each other is provided in this respect.

The deposition of energy into the first and second auxiliary layers may be performed by any known way, e.g., by mechanically working upon the coating layer, introducing heat by any suitable means, or the like.

Different possibilities are preferred for depositing the auxiliary layers. As a first option, step b or step c is performed by mechanically cladding the core precursor with a foil consisting of the auxiliary layer material. Such foils may consist of the core main component or of the coating component. Alternatively, the foils may consist of an alloy of the core main component and the coating component, wherein different foils may have different alloy compositions. Any choice of foil material may be made according to the demands of the resulting coating layer.

Such foils are usually applied at a stage when the core of the wire is in a precursor state and has a significant diameter, for example in the range of 50 mm. Aiming for a final wire diameter of e.g., 20 μm with a total thickness of the coating layer in the range of 80 nm, this would mean an initial total thickness of the foils in the range of 200 μm. Typically, palladium or copper foils are available down to a thickness of about 20 μm. Such foils are also available for the other coating components and core main components according to the invention. This would typically allow for stacking between 2 and 10 auxiliary layers of foils onto the core precursor.

After cladding the core precursor with the foils, the precursor is preferably extruded. After one or more extrusion steps, the precursor may undergo several drawing steps as known in the art until the final diameter of the wire is achieved. Depending on the wire thickness to be achieved, one or more intermediate annealing steps may be provided.

Alternatively, step b or step c may be performed by electroplating. Electroplating is usually performed on a wire core precursor with an intermediate thickness because electroplating directly on thin bonding wires is usually time and cost consuming. It is thus preferred to cover a thicker intermediate wire with thick auxiliary layers, wherein the final wire is achieved by several further drawing steps.

Further alternatively, step b or step c is performed by vapor deposition. The vapor deposition may comprise physical (PVD) or chemical (CVD) vapor deposition, though PVD is preferred for reasons of simplicity. Vapor deposition may in principle be performed on the final wire thickness or on an intermediate thickness, depending on the specific demands and costs.

A further aspect of the invention is an alternative method for manufacturing a wire according to the invention, comprising the steps of
a. providing a core precursor comprising copper or silver as a core main component; and
b. depositing a material to form a layer on the core precursor, in which the deposited material comprises at least 10% of the core main component and at least 10% of a coating component.

In particular, the coating layer or a precursor of the coating layer may be completely deposited by such a method.

In alternative specific embodiments of such a method, step b is performed by mechanically cladding the core precursor with a foil consisting of the layer material, electroplating the material, or vapor deposition of the material.

Any of these methods is suitable for depositing the coating layer or its precursor without the provision of several auxiliary layers.

For cladding the layer, a foil as described above may be used, which foil consists of an alloy of the core main component and the coating component as needed, such as a copper-palladium alloy.

For electroplating, a mixture of substances providing cations of the coating component, e.g., Pd-cations, as well as cations of the core main component, e.g., Cu-cations, may be used with an electroplating bath. Electroplating deposition of a defined alloy, e.g., a Cu—Pd-alloy, is provided by according control of the process parameters. The control of the parameters may even provide for a defined variation of the layer composition as needed.

For vapor deposition, it is also possible to directly deposit an alloy of the coating component and the core main component onto the wire core or core precursor. Similar to the method of electroplating, a variation of the layer composition depending on the depth of the layer may be adjusted if needed.

In the case of a most preferred embodiment, step b is performed by depositing a film of a liquid onto the wire core precursor, wherein the liquid contains a coating component precursor, and then heating the deposited film in order to decompose the coating component precursor into a metallic phase of the coating component.

Generally, such a coating component precursor may be a suitable organic compound containing the coating component as a metal ion. One specific example would an organic salt, e.g., an acetate, of the coating component.

Methods for direct deposition of palladium on other surfaces are known. For example, WO 98/38351 of The Whitaker Corporation, filed Feb. 24, 1998, describes a method of depositing palladium on metallic surfaces. It is pointed out that no electric current is used for the deposition of the metallic palladium. WO 98/38351 and the details of the deposition method described therein are incorporated herein by reference.

In a specific embodiment of the present invention, this method is used in order to provide a coating layer on a copper wire in which the coating layer comprises palladium as well as copper. Surprisingly, it has been found that even if the liquid does not contain any copper compound, the final coating layer comprises significant amounts of copper almost over its entire depth. One attempt for explaining this surprising effect is that copper oxide, which is usually present on a surface of the copper core, may allow for dissolution of copper or copper compounds in the deposited liquid film. According to the invention, the deposition method may also be used for further combinations of a coating component with a core main component as listed above.

For adjusting a thickness of the final coating layer, the thickness of the deposited film may be influenced. This may be achieved by adjusting the concentration of the coating component precursor. As a further measure, the viscosity of the liquid may be adjusted. One possible way is to use additives influencing the viscosity of the liquid. Such additives may be, for example, glycerine or any suitable substance with high viscosity.

Alternatively or additionally, the solvent may be chosen to have a specifically needed viscosity. For example, isopropyl alcohol may be chosen as a polar solvent which has a viscosity of more than 2.0 mPa*s (millipascal-second) at room temperature. The choice of the solvent may be further combined with the use of additives depending on the need.

Further alternatively or additionally, the deposition of the solvent may be performed at a controlled low temperature, in particular below 10° C., in order to provide for a high and/or defined viscosity.

Preferably, the liquid is chosen and/or adjusted so that it has a dynamic viscosity of more than 0.4 mPa*s at 20° C. More preferred, the viscosity is higher than 1.0 mPa*s, and most preferably higher than 2.0 mPa*s.

Examples of particular solvents in WO 98/38351 are methanol and DMSO. For the purpose of coating bonding wires, solvents containing sulfur, like, e.g., DMSO, are generally not preferred because the sulfur could have effects on the bonding and its related structures. It is preferred that elements contained in the liquid are limited to the group core main component (copper or silver), coating component (e.g. palladium etc.), noble metals, C, H, O, and N. Other elements should be contained below contamination levels of 1%, preferably below 0.1%.

In a preferred embodiment, the heating of the deposited film is performed at temperatures higher than 150° C., in particular between 150° C. and 350° C. This provides for quick and effective deposition of the palladium. Even more preferred, the heating is performed above 200° C., in particular between 200° C. and 300° C. Preferably, the film is still in liquid state when the heating is started.

The deposition and/or the heating is preferably performed dynamically on the moving wire.

In a generally preferred embodiment of the invention, the deposition of the film is performed after a final drawing step of the wire. This ensures that the deposited material keeps its original grain structure and particularly allows for highly isotropic grains. Such grain structure may help with good free air ball formation.

Generally, an inventive wire may preferably be treated in an annealing step at a temperature of at least 370° C. Even more preferred, the temperature of the annealing step is at least 430° C., wherein higher annealing temperatures may provide for higher elongation values of the wire.

Concerning further parameters for annealing, thin wires in particular need not be exposed to the annealing temperature for long. In most cases, annealing is done by pulling the wire through an annealing oven of a given length and with a defined temperature profile at a given speed. An exposure time of a thin wire to the annealing temperature is typically in the range of 0.1 second to 10 seconds.

It is pointed out that the above mentioned annealing steps may be performed before or after a deposition of the coating layer, depending on the method of manufacturing the wire. In some cases, it is preferred to avoid influencing the coating layer with high annealing temperatures. In such cases, the above mentioned methods, which allow for a deposition of the layer as a final manufacturing steps, are preferred.

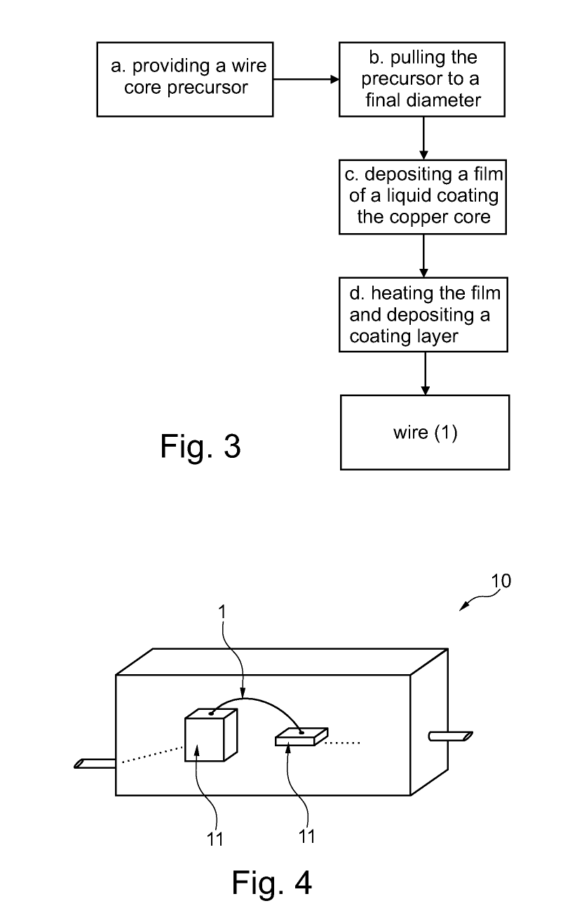

FIG. 3 is a flowchart for a process for manufacturing a wire according to the invention.

A further aspect of the invention is a system for bonding an electronic device comprising a first bonding pad, a second bonding pad and a wire according to the invention, wherein the wire is connected to at least one of the bonding pads by ball-bonding. This combination of an inventive wire in a system is preferred due to the fact that the wire has especially beneficial properties with respect to ball bonding.

A yet further aspect of the invention is a method for connecting an electrical device, comprising the steps
a. providing a wire according to the invention;
b. bonding the wire to a first bonding pad of the device by ball bonding or wedge bonding; and
c. bonding the wire to a second bonding pad of the device by wedge bonding;
wherein steps b and c are performed without using a forming gas.

FIG. 4 depicts an electric device 10 comprising two elements 11 and a wire 1. The wire 1 electrically connects the two elements 11. The dashed lines represent further connections or circuitry which connect the elements 11 with external wiring of a packaging device surrounding the elements 11. The elements 11 may comprise bond pads, integrated circuits, LEDs or the like.

The wire according to the invention shows excellent properties with respect to oxidation effects. This is particularly true if complete encapsulation of the copper core with the coating layer is present. The resulting properties allow for processing without using forming gas and hence lead to significant savings in costs and hazard precautions.

Forming gas is known in the art as a mixture of an inert gas like nitrogen with hydrogen, wherein the hydrogen content may provide for reduction reactions of oxidized wire material. In the sense of the invention, omitting of forming gas means that no reactive compound like hydrogen is used. Nevertheless, use of an inert gas like nitrogen may still be advantageous.

### Test Methods

All tests and measurements were conducted at T=20° C. and a relative humidity of 50%. The wire used for testing is a thin wire with a pure copper core (4N-copper) with a coating according to the invention. The diameter of the test wire is 20 μm (=0.8 mil).

### Layer Thickness

For determining the thickness of the coating layer, the thickness of the intermediate layer, and the diameter of the core, the wire was cut perpendicular to the maximum elongation of the wire. The cut was carefully ground and polished to avoid smearing of soft materials. A picture was recorded through a scanning electron microscope (SEM); the magnification was chosen so that the full cross-section of the wire was shown.

This procedure was repeated at least fifteen times and all values are provided as an arithmetic mean of the at least fifteen measurements.

### Grain Size

Several measurements on the microtexture of the wire surface were made, in particular by means of Electron Backscattering Diffractometry (EBSD). The analysis tool used was a FE-SEM Hitachi S-4300E. The software package used for measurement and data evaluation is called TSL and is commercially available from Edax Inc., US (www.edax.com). With these measurements, size and distribution of the crystal grains of the coating layer of the wire, as well as the crystal orientation, have been determined. As the measurement and evaluation of crystal grains is presently performed by EBSD measurement, it is to be understood that a tolerance angle of 5° was set for the determination of grain boundaries. The EBSD measurements were performed directly on the untreated surface of the coating layer.

### Ball-Wedge Bonding—Parameter Definition

Bonding of a wire to a substrate plated with gold was performed at 20° C., in which the bonding was applied to the gold surface. The device bond pad was Al-1% Si-0.5% Cu of 1 μm thickness, covered with >0.3 μm gold. After forming a first ball bond with an angle of 45° between the wire and the substrate, the wire was wedged with its second end to the substrate. The distance of the bonds between the two ends of the wire was in the range of from 5 to 20 mm. This distance was selected in order to assure the angle of 45° between the wire and the substrate. During wedge bonding, ultrasonic sound of a frequency in the range of 60-120 kHz was applied to the bondtool for 40 to 500 milliseconds.

The ball bonder equipment used was a K&S iConn with Copper Kit (S/W 8-88-4-43A-1). Testing device used was as K&S QFP 2×2 test device.

### Auger Depth Profiling

The depth profile of FIG. 6 was measured by following Auger-signals of the respective species (e.g. Cu, Pd, C) while sputtering the target surface at a constant sputter current density.

The sputter parameters were as follows:

Sputter ion: Xenon

Sputter angle: 90°

Sputter energy: 3.3 keV

Sputter area: 2 mm×2 mm

The depth profile was calibrated by comparison with a known standard sample. Eventual differences in the sputter rate of the sample and the standard were corrected accordingly. This results in the sputter rate, which is 8.0 nm/min in the profile of FIG. 6. As the sputter time is measured and the sputter current density is kept constant, the time scale of the profile is easily converted to a depth scale by multiplication with the sputter rate.

### Examples

The invention is further exemplified by examples. These examples serve for exemplary elucidation of the invention and are not intended to limit the scope of the invention or the claims in any way.

The following specific examples refer to a system of copper as a core main component and palladium as a coating component in the sense of the present invention. It is generally understood that in other embodiments, these components may be substituted by the respective other preferred components according to the invention. In particular, silver could be used instead of copper for the core main component and one or more of the group of Pt, Au, Rh, Ru, Os and Ir could be used instead of palladium for the coating component.

A quantity of copper material of at least 99.99% purity (“4N-copper”) is molten in a crucible. Then a wire core precursor of 5 mm diameter is cast from the melt.

First, the wire core precursor is extruded by an extrusion press until a further core precursor of less than 1 mm diameter is obtained. This wire core precursor is then drawn in several drawing steps to form the wire core 2 with a diameter of 20 μm. The cross section of the wire core 2 is of essentially circular shape. It is to be understood that the wire diameter is not considered to be a highly exact value due to fluctuations in the shape of the cross section, a thickness of the coating layer or the like. If a wire is presently defined to have a diameter of e.g., 20 μm, the diameter is understood to be in the range of 19.5 to 20.5 μm.

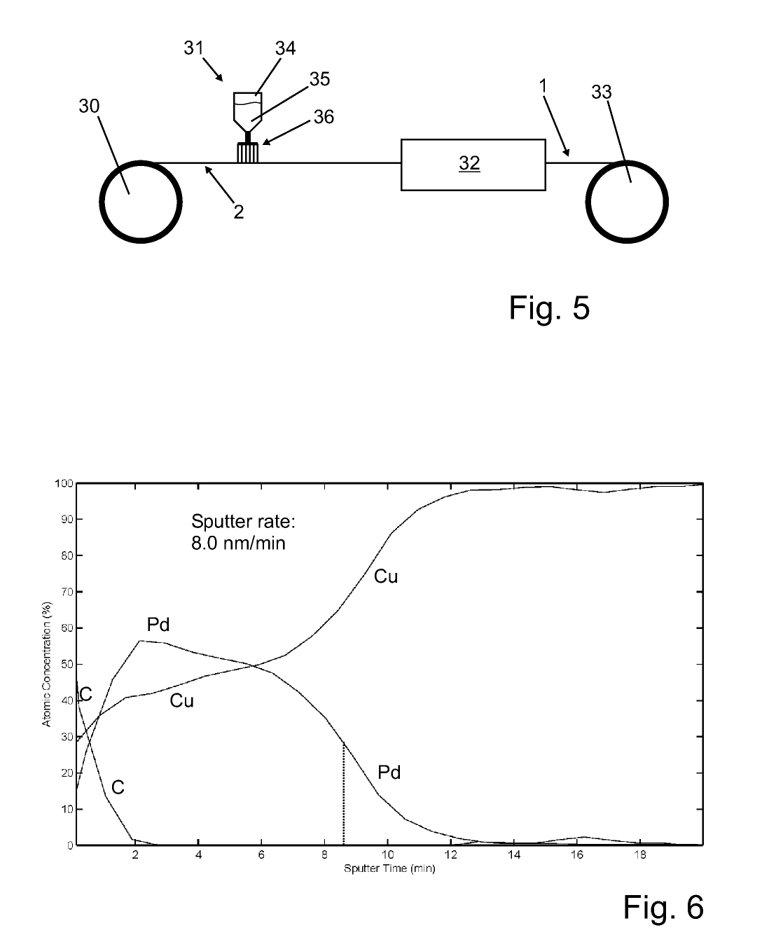

FIG. 5 is a sketch of a wire coating equipment. The wire 1 is unwound from a first reel 30, dynamically pulled through a depositing device 31 and an oven 32, and finally wound onto a second reel 33. The depositing device 31 comprises a reservoir 34 containing a liquid 35, which is dispensed onto the wire 1 by a dispenser 36 connected to the reservoir 34. The dispenser 36 may comprise a brush being in contact with the moving wire 1 or the like.

As shown in FIG. 5, this wire core is wound on the first reel 30 which is part of the device shown in FIG. 5. The wire 1 is then unwound from the first reel 30 and wound onto the second reel 33, wherein the wire may be pulled directly by turning the second reel 33 or by a further transport drive (not shown).

On its way along the span between the reels 30, 33, the wire first passes the depositing device 31. The reservoir 34 contains the liquid 35, which liquid is applied onto the wire 1 by the dispenser 36. The liquid 35 comprises isopropyl alcohol as a solvent. Palladium acetate (CH₃COO)₂Pd is dissolved in the solvent close to saturation level. The dynamic viscosity of the liquid 35 is adjusted to a value of about 2.5 mPa*s.

After dispensing the liquid onto the moving wire 1, the liquid forms a film of homogenous thickness on the surface of the wire core. This covered wire core then enters the oven 32, which is heated to 250° C. The length of the oven and the transport speed of the wire are adjusted such that the wire is exposed to the high temperature for about 5 seconds. By this exposure to the heat, the film dries out and the palladium-containing substances are reduced to metallic palladium. The metallic palladium is deposited on the wire core 1 and adds to forming the coating layer 3. Further components of the coating layer are copper and carbon or carbon compounds, which are typically collecting in an outer surface region of the coating layer.

As an alternative to providing the wire 1 from the first reel 30, the depositing device 31 and oven 32 may be provided directly in a drawing arrangement of the wire, preferably downwards of a last drawing die. It is to be understood that in the sense of the invention, there is no difference if such a direct arrangement is chosen or if the wire is provided from an intermediate reel 30 for the coating steps.

In the present example, the wire is annealed in an annealing step prior to the above described coating procedure. This annealing is performed in a known way in order to further adjust parameters like elongation, hardness, crystal structures and the like. The annealing is performed dynamically by running the wire through an annealing oven of a defined length and temperature with a defined speed. After leaving the oven, the uncoated wire is spooled on the first reel 30. It is understood that for most applications, the temperatures in such an annealing step for the adjustment of, e.g., an elongation value of the wire, are much higher (typically higher than 370° C.) than the temperatures needed for the coating layer deposition. Therefore, the microstructure of the wire core is not usually influenced in a significant way if the coating is performed as a last step.

In other embodiments of the invention, the layer deposition and the wire core annealing may be combined in a single heating step. In such an arrangement, a defined heating profile may be used, which may be adjusted by special oven setups.

The resulting wire of the present embodiment showed a surface with very symmetric grains and a narrow grain size distribution. These data were collected by EBSD measurements.

TABLE 1

| Grain size circumferential direction [nm] | max | min | average |
|---|---|---|---|
| Inventive wire | 700 | 100 | 320 |
| Conventional wire | 300 | 90 | 180 |

The above Table 1 shows a comparison between the grain sizes of an inventive wire and a conventional wire. In the case of the conventional wire, the core has been electroplated with pure palladium and undergone several drawing steps afterwards.

In the longitudinal direction, the average grain size for the inventive wire is 300 nm, resulting in a value of 0.94 for a ratio of longitudinal to circumferential average grain size.

Further, a sample of the wire was cut for determination of the layer thickness by SEM as described above. An average of the measured layer thickness at different positions was calculated to be 92.6 nm.

In FIG. 6, an Auger profile of the sample wire is displayed. Material was sputtered homogenously from the wire surface in a defined area by an ion beam. Several Auger signals from different elements (displayed: carbon C, copper Cu and palladium Pd) were followed, depending on the sputter time. The sputter rate was calibrated by means of a known Ta₂O₅-sample, giving a sputter rate of about 8 nm per minute. The interface of the coating layer and the core was defined as a 50% drop of the Pd-Signal from a maximum value. This gives an estimated thickness of the coating layer of about 84 nm, which is in good correlation with the average layer thickness measured by SEM.

As the wire has a diameter of 20 μm and the coating layer has a thickness of 92.6 nm, the coating layer extends from a depth of 0% of the diameter up to a depth of 0.48% of the wire diameter.

The depth profile from FIG. 6 shows that, starting with a radially outward surface of the layer, carbon is the main component at the outer region. Within the first few monolayers, the carbon signal drops sharply, while the palladium and copper signals increase. It is noted that there is nearly no palladium signal on the outermost surface, although the signal increases immediately with the start of the sputtering.

Next, the palladium signal or concentration exceeds the carbon signal at a depth of about 3 nm, marking a first change of the main component of the surface.

The copper signal reaches a local maximum at a depth of about 8 nm. The palladium and the copper signal show an almost constant value over a depth range from 10 nm to 60 nm, wherein palladium is at a level between 55% and 60% and copper is at a level of 40% to 45%. No other elements are present in significant amounts in this region.

Then the palladium signal starts to drop, and copper becomes the main component at a depth of about 65 nm, marking a second change of the main component within the coating layer.

The average thickness of the coating layer for the purpose of the present invention is the average thickness measured by SEM.

The Auger depth profiling as described above is used for definition of the coating layer composition and the distribution of the single components in the layer.

An outer range of the coating layer is defined as extending from 0.1% wire diameter (=20 nm) to 0.25% wire diameter (=about 50 nm). It is obvious that in this range, copper is present in an amount of more than 30%. Further, the palladium starts to drop to lower values with increasing depth within the outer range. Nevertheless, the palladium concentration drops by just a few percent within this range.

It is noted that the given depth scale of the Auger profile is sufficiently correct, as the good correlation with the average layer thickness measured by SEM confirms.

The wire sample was tested in the above described test procedures for ball bonding and wedge bonding (second bonding). Pull tests and ball shearing tests have been performed as usual testing procedures. The results have shown that the sample wire according to the invention develops a very symmetric free air ball with good reproducibility. Further, the second bond did not show any disadvantages with respect to second bonding window.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-21. (canceled)

22. A bonding wire comprising a core having a surface and a coating layer which is at least partially superimposed over the surface of the core, wherein the core comprises a core main component selected from the group consisting of copper and silver; and wherein the coating layer comprises a coating component selected from the group consisting of palladium, platinum, gold, rhodium, ruthenium, osmium and iridium in an amount of at least 10% and further comprises the core main component in an amount of at least 10%.

23. The wire according to claim 22, wherein an outer range of the coating layer extends from a depth of 0.1% of a wire diameter to a depth of 0.25% of the wire diameter, and wherein the amount of the core main component and the amount of the coating component are present in the outer range.

24. The wire according to claim 23, wherein the amount of the core main component in the outer range is between 30% and 70%.

25. The wire according to claim 23, wherein the amount of the coating component decreases within the outer range toward an inside of the wire.

26. The wire according to claim 25, wherein a difference of the amount of the coating component at a radially inner border of the outer range and the amount of the coating component at a radially outer border of the outer range is not more than 30%.

27. The wire according to claim 22, wherein a main component of the wire changes at least two times starting from an outside of the wire up to a depth of 0.25% of a diameter of the wire.

28. The wire according to claim 22, wherein an outer surface range of the coating layer contains carbon as a main component.

29. The wire according to claim 22, wherein an average grain size of the coating layer measured at the wire surface in a longitudinal direction of the wire is between 50 nm and 1000 nm.

30. The wire according to claim 22, wherein a ratio a/b of an average grain size a of the coating layer measured at the wire surface in a longitudinal direction of the wire and an average grain size b of the coating layer measured at the wire surface in a circumferential direction of the wire is between 0.1 and 10.

31. A method for manufacturing a wire according to claim 22, comprising the steps of:
a. providing a core precursor comprising copper or silver as a main component;
b. depositing a first auxiliary layer on the core precursor, wherein the first auxiliary layer comprises one of the core main component and the coating component as a main component;
c. depositing a second auxiliary layer on the first auxiliary layer, wherein the second layer comprises the other of the core main component and the coating component as a main component; and
d. introducing energy into at least the first layer and the second layer to at least partially mix the materials of the first and second layers.

32. The method according to claim 31, wherein step b or step c is performed by mechanically cladding the core precursor with a foil consisting of the auxiliary layer material.

33. The method according to claim 31, wherein step b or step c is performed by electroplating.

34. The method according to claim 31, wherein step b or step c is performed by vapor deposition.

35. A method for manufacturing a wire according to claim 22, comprising the steps of
a. providing a core precursor comprising copper or silver as a core main component; and
b. depositing a material to form a layer on the core precursor, wherein the deposited material comprises at least 10% of the core main component and at least 10% of the coating component.

36. The method according to claim 35, wherein step b is performed by mechanically cladding the core precursor with a foil consisting of the layer material, electroplating the layer material, or vapor deposition of the layer material.

37. The method according to claim 35, wherein step b is performed by depositing a film of a liquid onto the wire core precursor, wherein the liquid contains a coating component precursor, and wherein the deposited film is heated to decompose the coating component precursor into a metallic phase.

38. The method according to claim 37, wherein the liquid has a dynamic viscosity of more than 0.4 mPa*s at 20° C.

39. The method according to claim 38, wherein the heating of the deposited film is performed at temperatures higher than 150° C.

40. The method according to claim 35, wherein the deposition of the film is performed after a final drawing step of the wire.

41. A system for bonding an electronic device, comprising a first bonding pad, a second bonding pad and a wire according to claim 1, wherein the wire is connected to at least one of the first and second bonding pads by ball-bonding.

42. A method for connecting an electrical device, comprising:
a. providing a wire according to claim 1;
b. bonding the wire to a first bonding pad of the electrical device by ball bonding or wedge bonding; and
c. bonding the wire to a second bonding pad of the electrical device by wedge bonding;
wherein steps b and c are performed without using a forming gas.
